(19) United States
(12) Patent Application Publication
(10) Pub. No.: US 2015/0204934 A1
(43) Pub. Date: Jul. 23, 2015

(54) METHOD OF DETERMINING A CHARACTERISTIC OF A POWER TRANSFORMER AND A SYSTEM THEREFOR

(71) Applicant: Ahmed Mohamed Ahmed Abu Siada, Shelley WA (AU)

(72) Inventor: Ahmed Mohamed Ahmed Abu Siada, Shelley WA (AU)

(73) Assignee: CURTIN UNIVERSITY OF TECHNOLOGY, Bentley WA (AU)

(21) Appl. No.: 14/416,980

(22) PCT Filed: Jul. 23, 2012
(86) PCT No.: PCT/AU2012/000874

§ 371 Date: Jan. 27, 2015

(51) Int. Cl. G01R 31/02; G01R 31/40

(52) U.S. Cl. CPC G01R 31/027; G01R 31/40

(57) ABSTRACT

A method of determining a characteristic of a power transformer is provided. The power transformer has an input current, an input voltage, an output current and an output voltage. The method comprises measuring the input current and a voltage difference between the input voltage and the output voltage of the power transformer while the power transformer is in use within a power distribution network. Information that is indicative of at least one property of a test locus plot from the measured input current and voltage difference of the power transformer is derived and compared to information that is indicative of at least one property of a reference locus plot associated with a reference power transformer. From the comparison, it is determined whether a characteristic of the power transformer differs from that of the reference power transformer.

### FIELD OF THE INVENTION

The present invention relates to a method of detecting a characteristic of a power transformer and a system therefor.

### BACKGROUND OF THE INVENTION

Power transformers are critical components within electrical transmission and distribution systems. Failure of a power transformer, when in service, can result in an extended power outage, costly repairs and/or serious injury or fatality.

When in operation, a power transformer is exposed to faults, switching transients, and other system events that result in magnetic forces being imposed on windings of the power transformer. If these forces exceed certain thresholds, then winding deformation can occur.

Although power transformers are designed to survive a number of short-circuit faults without failing, if a power transformer has been subjected to winding deformation, the likelihood of surviving further short-circuits can be reduced due to locally increased electromagnetic stresses.

Currently, frequency-response analysis (FRA) is used to detect winding deformation of a power transformer, however this technique involves switching the power transformer off and taking the power transformer out of service, which can lead to power network disruptions. Further, the interpretation of FRA results is a highly specialized area and requires expert personnel to determine the type and possible location of the fault.

### SUMMARY OF THE INVENTION

In accordance with a first aspect of the present invention, there is provided a method of determining a characteristic of a power transformer, the power transformer having an input current, an input voltage, an output current and an output voltage, the method comprising the steps of:
measuring the input current and a voltage difference between the input voltage and the output voltage of the power transformer while the power transformer is in use within a power distribution network;
deriving information that is indicative of at least one property of a test locus plot from the measured input current and voltage difference of the power transformer;
comparing the information that is indicative of the at least one property of the test locus plot to information that is indicative of at least one property of a reference locus plot associated with a reference power transformer so as to determine whether a characteristic of the power transformer differs from that of the reference power transformer.

The step of comparing may comprise comparing the test locus plot to the reference locus plot so as to determine visual differences therebetween, and/or comparing ellipse features of the test locus plot to ellipse features of the reference locus plot so as to determine differences therebetween.

In accordance with a second aspect of the present invention, there is provided a method of determining a characteristic of a power transformer, the power transformer having an input current, an input voltage, an output current and an output voltage, the method comprising the steps of:
measuring the input current and a voltage difference between the input voltage and the output voltage of the power transformer;
deriving information that is indicative of at least one property of a test locus plot from the measured input current and voltage difference of the power transformer;
comparing the information that is indicative of the at least one property of the test locus plot to information that is indicative of at least one property of a reference locus plot associated with a reference power transformer so as to determine whether a characteristic of the power transformer differs from that of the reference power transformer;
wherein the step of comparing comprises comparing the test locus plot to the reference locus plot so as to determine visual differences therebetween, and/or comparing ellipse features of the test locus plot to ellipse features of the reference locus plot so as to determine differences therebetween.

The input current and the voltage difference of the power transformer may be measured while the power transformer is in use within a power distribution network.

The following introduces features of the method in accordance with the first and/or the second aspects.

In one embodiment, the characteristic is a characteristic of at least one winding of the power transformer. The characteristic of the at least one winding of the power transformer may be a characteristic for which a chance of the power transformer failing increases if the power transformer is subjected to a fault, for example a short-circuit fault, if the characteristic differs from that of the reference power transformer.

In one embodiment, the power transformer is energized by an alternating current having a mains frequency of an electrical network to which the power transformer is, in use, connected.

In one embodiment, the method comprises a step of categorising the characteristic of the at least one winding based on the comparing step. The characteristic of the at least one winding may be categorised as any one of the group comprising: an interdisk fault, an axial displacement fault, a buckling stress fault, a leakage (disk to ground) fault, and a disk space variation fault.

The step of comparing may comprise comparing the test locus plot to the reference locus plot so as to determine visual differences therebetween, and the method may comprise the step of determining whether the characteristic of the at least one of the windings of the power transformer differs from that of the reference power transformer based on any visual differences between the test locus plot and the reference locus plot.

Visual differences that are determined may include a rotation of the test locus plot compared to the reference locus plot, and/or a change in an area of an internal region of the test locus plot compared to the reference locus plot.

Determined visual differences between the test locus plot and the reference locus plot may be used to categorise the characteristic of the at least one winding.

An interdisk fault may be determined by determining that the test locus plot rotates clockwise and an area of an internal region of the test locus plot increases compared to the reference locus plot. A magnitude of the interdisk fault may be determined based on an amount by which the test locus plot rotates clockwise and increases in area compared to the reference locus plot.

An axial displacement fault may be determined by determining that an area of an internal region of the test locus plot decreases compared to the reference locus plot, but wherein the test locus plot undergoes no substantial rotation compared to the reference locus plot. A magnitude of the axial displacement fault may be determined based on an amount by which the area of the test locus plot decreases compared to the reference locus plot.

A buckling stress fault may be determined by determining that the test locus plot rotates clockwise and an area of an internal region of the test locus plot increases compared to the reference locus plot, wherein the test locus plot rotates clockwise with a smaller magnitude than that of a comparable interdisk fault. A magnitude of the buckling stress fault may be determined based on an amount by which the test locus plot rotates clockwise and increases in area compared to the reference locus plot.

A leakage fault may be determined by determining that the test locus plot rotates clockwise and an area of an internal region of the test locus plot increases compared to the reference locus plot, wherein the area of the test locus plot increases with a larger magnitude than that of a comparable interdisk fault. A magnitude of the leakage fault may be determined based on an amount by which the test locus plot rotates clockwise and increases in area compared to the reference locus plot.

A disk space variation fault may be determined by determining that the test locus plot rotates clockwise and a length of a major axis of the test locus plot increases compared to the reference locus plot. A magnitude of the leakage fault may be determined based on an amount by which the test locus plot rotates clockwise and the major axis increases compared to the reference locus plot.

The step of comparing may comprise comparing ellipse features of the test locus plot to ellipse features of the reference locus plot so as to determine differences therebetween, and the method may comprise the step of determining whether the characteristic of the at least one of the windings of the power transformer differs from that of the reference power transformer based on any differences between the ellipse features of the test locus plot and the reference locus plot.

Ellipse feature differences that are determined may include an ellipse centroid, major and/or minor axes lengths (a and b respectively), an angle between the major axis and a horizontal axis (θ), and an ellipse eccentricity.

The ellipse eccentricity may be calculated from the equation:

e=(1−(b/a)²)^{1/2}

wherein:
e is an ellipse eccentricity of a locus plot;
b is a major axis length of a locus plot; and
a is a minor axis length of a locus plot.

Determined ellipse feature differences between the test locus plot and the reference locus plot may be used to categorise the characteristic of the at least one winding.

An interdisk fault may be determined by determining that the eccentricity (e) and the angle between the major axis and the horizontal axis (θ) increases compared to the reference locus plot. A magnitude of the interdisk fault may be determined based on an amount by which e and θ of the test locus plot increase compared to the reference locus plot.

An axial displacement fault may be determined by determining that the eccentricity (e) of the test locus plot increases compared to the reference locus plot, but that the angle between the major axis and the horizontal axis (θ) of the test locus plot undergoes no substantial change compared to the reference locus plot. A magnitude of the axial displacement fault may be determined based on an amount by which e of the test locus plot increases compared to the reference locus plot.

A buckling stress fault may be determined by determining that the eccentricity (e) and the angle between the major axis and the horizontal axis (θ) increases compared to the reference locus plot. A magnitude of the buckling stress fault may be determined based on an amount by which e and θ of the test locus plot increase compared to the reference locus plot.

A leakage fault may be determined by determining that the eccentricity (e) and the angle between the major axis and the horizontal axis (θ) increases compared to the reference locus plot, wherein the increase in e is larger and the increase in θ is smaller than that of a comparable budding stress fault. A magnitude of the budding stress fault may be determined based on an amount by which e and θ of the test locus plot increase compared to the reference locus plot.

A disk space variation fault may be determined by determining that the angle between the major axis and the horizontal axis (θ) increases compared to the reference locus plot, and wherein the eccentricity (e) of the test locus plot increases slightly compared to the reference locus plot. A magnitude of the disk space variation fault may be determined based on an amount by which e and θ of the test locus plot increase compared to the reference locus plot.

The step of categorising the characteristic of the at least one winding may comprise comparing the determined visual differences and/or the determined ellipse feature differences to predefined values or a range of predefined values so as to categorise the characteristic of the at least one winding. The step of categorising the characteristic of the at least one winding may be performed in an automated fashion.

In one embodiment, the input current and the voltage difference of the power transformer are measured each cycle of the mains frequency. The step of determining whether the characteristic of the power transformer differs from that of the reference power transformer may be performed based on each set of input current and voltage difference as measured each cycle of the mains frequency.

In one embodiment, the method comprises storing information indicative of the characteristic as determined over time. The method may further comprise analysing the information indicative of the characteristic over time so as to determine an appropriate time to perform additional testing of the power transformer, such as frequency response analysis testing of the power transformer.

In one embodiment, the method comprises generating an alert if the characteristic of the power transformer differs from that of the reference power transformer by a predefined amount.

The information that is indicative of the at least one property of the reference locus plot may be obtained from a reference power transformer, the reference power transformer having a plurality of windings, and having an input current, an input voltage, an output current and an output voltage, by.
measuring the input current and a voltage difference between the input voltage and the output voltage of the reference power transformer; and
deriving the information that is indicative of the at least one property of the reference locus plot from the measured input current and voltage difference of the reference power transformer.

The reference power transformer may be the power transformer or a further power transformer. The reference power transformer may be a virtual power transformer.

In one example, the information that is indicative of the at least one property of the reference locus plot is obtained by:
simulating a reference power transformer as an electrical circuit that is substantially equivalent to a power transformer; and
measuring an input current and a voltage difference between an input voltage and an output voltage of the substantially equivalent electrical circuit; and
deriving the information that is indicative of the at least one property of the reference locus plot from the measured input current and voltage difference of the substantially equivalent electrical circuit.

In accordance with a third aspect of the present invention, there is provided a system for determining a characteristic of a power transformer, the power transformer having an input current, an input voltage, an output current and an output voltage, the system comprising:
data storage arranged to store information that is indicative of at least one property of a reference locus plot associated with a reference power transformer;
a current and voltage measurement system arranged to measure the input current and a voltage difference between the input voltage and the output voltage of the power transformer while the power transformer is in use within a power distribution network;
a test locus plot processing module arranged to derive information that is indicative of at least one property of a test locus plot from the measured input current and voltage difference of the power transformer;
a comparison processing module that is arranged to compare the information that is indicative of the at least one property of the test locus plot to information that is indicative of at least one property of a reference locus plot associated with a reference power transformer so as to determine whether a characteristic of the power transformer differs from that of the reference power transformer.

The comparison processing module may be arranged to compare the test locus plot to the reference locus plot so as to determine visual differences therebetween, and/or to compare ellipse features of the test locus plot to ellipse features of the reference locus plot so as to determine differences therebetween.

In accordance with a fourth aspect of the present invention, there is provided a system for determining a characteristic of a power transformer, the power transformer having an input current, an input voltage, an output current and an output voltage, the system comprising:
data storage arranged to store information that is indicative of at least one property of a reference locus plot associated with a reference power transformer;
a current and voltage measurement system arranged to measure the input current and a voltage difference between the input voltage and the output voltage of the power transformer;
a test locus plot processing module arranged to derive information that is indicative of at least one property of a test locus plot from the measured input current and voltage difference of the power transformer;
a comparison processing module that is arranged to compare the information that is indicative of the at least one property of the test locus plot to information that is indicative of at least one property of a reference locus plot associated with a reference power transformer so as to determine whether a characteristic of the power transformer differs from that of the reference power transformer;
wherein the comparison processing module is arranged to compare the test locus plot to the reference locus plot so as to determine visual differences therebetween, and/or to compare ellipse features of the test locus plot to ellipse features of the reference locus plot so as to determine differences therebetween.

The system may be arranged such that the input current and the voltage difference of the power transformer are measured while the power transformer is in use within a power distribution network.

The following introduces features of the system in accordance with the third and/or the fourth aspects.

In one embodiment, the characteristic is a characteristic of at least one winding of the power transformer. The characteristic of the at least one winding of the power transformer may be a characteristic for which a chance of the power transformer falling increases if the power transformer is subjected to a fault, for example a short-circuit fault, if the characteristic differs from that of the reference power transformer.

In one embodiment, the power transformer is energized by an alternating current having a mains frequency of an electrical network to which the power transformer is, in use, connected.

In one embodiment, the system comprises a characteristic categorising processing module arranged to categorise the characteristic of the at least one winding based on a comparison conducted by the comparison processing module. The characteristic of the at least one winding may be categorised as any one of the group comprising: an interdisk fault, an axial displacement fault, a buckling stress fault, a leakage (disk to ground) fault, and a disk space variation fault.

The comparison processing module may be arranged to compare the test locus plot to the reference locus plot so as to determine visual differences therebetween, and the system may be arranged to determine whether the characteristic of the at least one of the windings of the power transformer differs from that of the reference power transformer based on any visual differences between the test locus plot and the reference locus plot.

Visual differences that are determined may include a rotation of the test locus plot compared to the reference locus plot, and/or a change in an area of an internal region of the test locus plot compared to the reference locus plot.

Determined visual differences between the test locus plot and the reference locus plot may be used by the system to categorise the characteristic of the at least one winding.

The system may be arranged to determine an interdisk fault by determining that the test locus plot rotates clockwise and an area of an internal region of the test locus plot increases compared to the reference locus plot. A magnitude of the interdisk fault may be determined based on an amount by which the test locus plot rotates clockwise and increases in area compared to the reference locus plot.

The system may be arranged to determine an axial displacement-fault by determining that an area of an internal region of the test locus plot decreases compared to the reference locus plot, but wherein the test locus plot undergoes no substantial rotation compared to the reference locus plot A magnitude of the axial displacement fault may be determined based on an amount by which the area of the test locus plot decreases compared to the reference locus plot.

The system may be arranged to determine a buckling stress fault by determining that the test locus plot rotates clockwise and an area of an internal region of the test locus plot increases compared to the reference locus plot, wherein the test locus plot rotates clockwise with a smaller magnitude than that of a comparable interdisk fault. A magnitude of the buckling stress fault may be determined based on an amount by which the test locus plot rotates clockwise and increases in area compared to the reference locus plot.

The system may be arranged to determine a leakage fault by determining that the test locus plot rotates clockwise and an area of an internal region of the test locus plot increases compared to the reference locus plot, wherein the area of the test locus plot increases with a larger magnitude than that of a comparable interdisk fault. A magnitude of the leakage fault may be determined based on an amount by which the test locus plot rotates clockwise and increases in area compared to the reference locus plot.

The system may be arranged to determine a disk space variation fault by determining that the test locus plot rotates clockwise and a length of a major axis of the test locus plot increases compared to the reference locus plot. A magnitude of the leakage fault may be determined based on an amount by which the test locus plot rotates clockwise and the major axis increases compared to the reference locus plot.

The comparison processing module may be arranged to compare ellipse features of the test locus plot to ellipse features of the reference locus plot so as to determine differences therebetween, and the system may be arranged to determine whether the characteristic of the at least one of the windings of the power transformer differs from that of the reference power transformer based on any differences between the ellipse features of the test locus plot and the reference locus plot.

Ellipse feature differences that are determined may include an ellipse centroid, major and/or minor axes lengths (a and b respectively), an angle between the major axis and a horizontal axis (θ), and an ellipse eccentricity.

The ellipse eccentricity may be calculated from the equation:

e=(1−(b/a))²)^{1/2}

wherein:
e is an ellipse eccentricity of a locus plot;
b is a major axis length of a locus plot; and
a is a minor axis length of a locus plot.

Determined ellipse feature differences between the test locus plot and the reference locus plot may be used to categorise the characteristic of the at least one winding.

The system may be arranged to determine an interdisk fault by determining that the eccentricity (e) and the angle between the major axis and the horizontal axis (θ) increases compared to the reference locus plot. A magnitude of the interdisk fault may be determined based on an amount by which e and θ of the test locus plot increase compared to the reference locus plot.

The system may be arranged to determine an axial displacement fault by determining that the eccentricity (e) of the test locus plot increases compared to the reference locus plot, but that the angle between the major axis and the horizontal axis (θ) of the test locus plot undergoes no substantial change compared to the reference locus plot. A magnitude of the axial displacement fault may be determined based on an amount by which a of the test locus plot increases compared to the reference locus plot.

The system may be arranged to determine a buckling stress fault by determining that the eccentricity (e) and the angle between the major axis and the horizontal axis (θ) increases compared to the reference locus plot. A magnitude of the buckling stress fault may be determined based on an amount by which e and θ of the test locus plot increase compared to the reference locus plot.

The system may be arranged to determine a leakage fault by determining that the eccentricity (e) and the angle between the major axis and the horizontal axis (θ) increases compared to the reference locus plot, wherein the increase in e is larger and the increase in θ is smaller than that of a comparable buckling stress fault. A magnitude of the buckling stress fault may be determined based on an amount by which e and θ of the test locus plot increase compared to the reference locus plot.

The system may be arranged to determine a disk space variation fault by determining that the angle between the major axis and the horizontal axis (θ) increases compared to the reference locus plot, and wherein the eccentricity (e) of the test locus plot increases slightly compared to the reference locus plot. A magnitude of the disk space variation fault may be determined based on an amount by which e and θ of the test locus plot increase compared to the reference locus plot.

The characteristic categorising processing module may be arranged to compare the determined visual differences and/or the determined ellipse feature differences to predefined values or a range of predefined values so as to categorise the characteristic of the at least one winding.

In one embodiment, the input current and the voltage difference of the power transformer are measured each cycle of the mains frequency. The system may be arranged to determine whether the characteristic of the at least one winding of the power transformer differs from that of the reference power transformer based on each set of input current and voltage difference as measured each cycle of the mains frequency.

In one embodiment, the system is arranged to store information indicative of the characteristic as determined over time in the data storage. The system may further be arranged to analyse the information indicative of the characteristic over time so as to determine an appropriate time to perform additional testing of the power transformer, such as frequency response analysis testing of the power transformer.

In one embodiment, the system is arranged to generate an alert if the characteristic of the at least one winding of the power transformer differs from that of the reference power transformer by a predefined amount.

The information that is indicative of the at least one property of the reference locus plot may be obtained from a reference power transformer, the reference power transformer having a plurality of windings, and having an input current, an input voltage, an output current and an output voltage, by:
measuring the input current and a voltage difference between the input voltage and the output voltage of the reference power transformer; and
deriving the information that is indicative of the at least one property of the reference locus plot from the measured input current and voltage difference of the reference power transformer.

The reference power transformer may be the power transformer or a further power transformer. The reference power transformer may be a virtual power transformer.

In one example, the information that is indicative of the at least one property of the reference locus plot is obtained by:
simulating a reference power transformer as an electrical circuit that is substantially equivalent to a power transformer; and
measuring an input current and a voltage difference between an input voltage and an output voltage of the substantially equivalent electrical circuit; and
deriving the information that is indicative of the at least one property of the reference locus plot from the measured input current and voltage difference of the substantially equivalent electrical circuit.

In accordance with a fifth aspect of the present invention, there is provided a computer program arranged when loaded into a computing device to instruct the computing device to operate in accordance with the method of the first or the second aspects.

In accordance with a sixth aspect of the present invention, there is provided a computer readable medium having a computer readable program code embodied therein for causing a computing device to operate in accordance with the method of the first or the second aspects.

In accordance with a seventh aspect of the present invention, there is provided a data signal having a computer readable program code embodied therein to cause a computing device to operate in accordance with the method of the first or the second aspects.

### BRIEF DESCRIPTION OF THE DRAWINGS

In order that the present invention may be more clearly ascertained, embodiments of the present invention will now be described, by way of example only, with reference to the accompanying drawings, in which:

FIG. 1 is a flow diagram of a method of determining a characteristic of a power transformer in accordance with an embodiment of the present invention;

FIG. 2a is a per-unit equivalent circuit of a power transformer of FIG. 1;

FIG. 2b is a phasor diagram of the per-unit equivalent circuit of FIG. 2a;

FIG. 3 is a graphical representation of construction of a locus plot of a power transformer;

FIG. 4 is a locus plot of a power transformer illustrating an impact of a load power factor on the locus plot;

FIG. 5 is a transformer distributed parameter model used to model a power transformer;

FIG. 6 is a locus plot of a power transformer illustrating an impact of a load level on the locus plot;

FIG. 7 is a locus plot of a healthy power transformer;

FIG. 8 is a locus plot illustrating an interdisk fault compared to a healthy power transformer;

FIG. 9 is a locus plot illustrating an interdisk fault compared to a healthy power transformer;

FIG. 10 is a locus plot illustrating an axial displacement fault compared to a healthy power transformer;

FIG. 11 is a locus plot illustrating a forced buckling fault compared to a healthy power transformer;

FIG. 12 is a locus plot illustrating a disk-to-ground fault compared to a healthy power transformer;

FIG. 13 is a locus plot illustrating disk space variation fault compared to a healthy power transformer;

FIG. 14 is a locus plot illustrating various faults compared to a healthy power transformer;

FIG. 15 is a locus plot illustrating various faults on five disks of a power transformer compared to a healthy power transformer;

FIG. 16 is a visual comparison of two identical power transformer loci;

FIG. 17 is a visual comparison of a faulty power transformer locus and a healthy power transformer locus;

FIG. 18 is a locus plot of a power transformer with a six-disk axial displacement fault compared to a locus plot of a healthy power transformer;

FIG. 19 is a locus plot of a power transformer with a three-disk leakage fault compared to a locus plot of a healthy power transformer;

FIG. 20 is a locus plot of a power transformer with a one-disk space variation fault compared to a locus plot of a healthy power transformer;

FIG. 21 is a locus plot of a power transformer with various practical turn-to-turn faults compared to a locus plot of a healthy power transformer;

FIG. 22 is a visual comparison of a locus of a power transformer having a practical fault and a healthy power transformer locus; and

FIG. 23 is a schematic diagram of a system for determining a characteristic of a power transformer in accordance with an embodiment of the present invention.

### DESCRIPTION OF AN EMBODIMENT OF THE INVENTION

Embodiments of the present invention relate to a method of detecting a characteristic of a power transformer and a system therefor. In general, the method and the system are directed to measuring an input current and a difference between an input voltage and an output voltage of a power transformer, and using this information to generate a test locus plot of the power transformer.

The test locus plot, or at least one feature thereof, is then compared to a reference locus plot, or at least one feature thereof, so as to determine any differences therebetween. Identified differences between the test locus plot and the reference locus plot, such as a difference in area, or a rotation of the test locus plot compared to the reference locus plot, or a difference in elliptical features, can be used to identify a type of internal mechanical fault of the power transformer.

In this way, internal mechanical faults that reduce a chance of the power transformer surviving a fault such as a short-circuit fault can be identified without taking the power transformer offline for other types of testing, such as frequency-response analysis (FRA) testing.

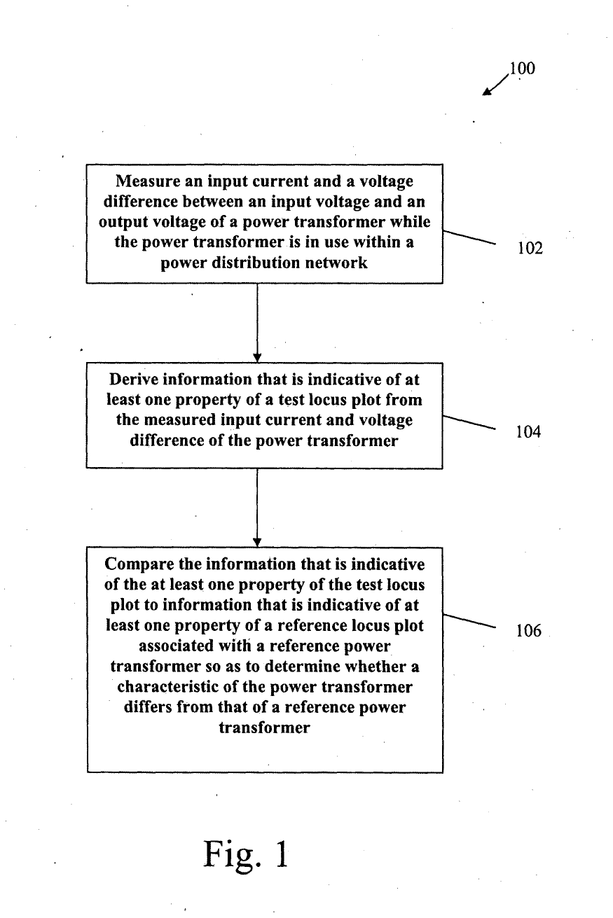

An example method 100 is illustrated in FIG. 1. In a first step 102, an input current and a voltage difference between an input voltage and an output voltage of a power transformer are measured while the power transformer is in use within a power distribution network. As the power transformer is in operation, the power transformer is energized by an alternating current having a mains frequency of an electrical network to which the power transformer is connected to.

In a second step 104, information that is indicative of at least one property of a test locus plot is derived from the measured input current and voltage difference of the power transformer.

In a third step 106, the information that is indicative of the at least one property of the test locus plot is compared to information that is indicative of at least one property of a reference locus plot associated with a reference power transformer so as to determine whether a characteristic of the power transformer differs from that of the reference power transformer.

The reference power transformer may be the same power transformer that is being measured, wherein the reference locus plot was obtained at an earlier point in time, such as when the power transformer was first commissioned. Alternatively, the reference power transformer may be a power transformer that has substantially the same design characteristics as the power transformer that is being measured, or the reference transformer may be a virtual transformer that is simulated so as to have an electrical circuit that is substantially equivalent to the power transformer.

Typically, the characteristic of the at least one winding of the power transformer is a characteristic for which a chance of the power transformer falling increases if the power transformer is subjected to a fault, for example a short-circuit fault, if the characteristic differs from that of the reference power transformer. Example characteristics include: an interdisk fault, an axial displacement fault, a budding stress fault, a leakage (disk to ground) fault, and a disk space variation fault.

An example of locus plot construction will now be described.

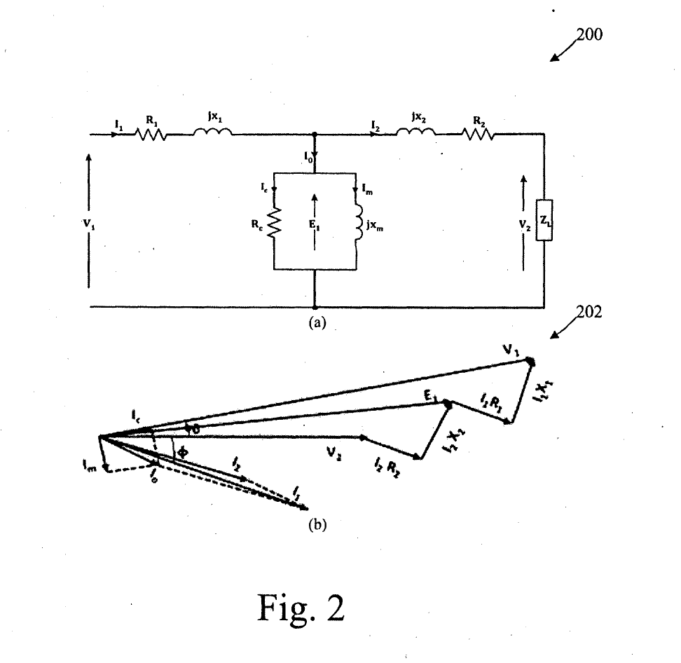

In this example, the method 100 comprises constructing a locus diagram relating the power transformer input current on the x axis and the difference between the input and output voltages of a particular phase on the y axis. The relationship relating the aforementioned parameters can be derived using a single-phase transformer equivalent circuit 200 and its phasor diagram 202 as shown in FIG. 2.

Let:

v₂(t)=Vₘ₂ sin(ωt) (1)

v₁(t)=Vₘ₁ sin(ωt+δ) (2)

x=i₁(t)=Iₘ₁ sin(ωt−φ). (3)

For simplicity, assume Vₘ₁=Vₘ₂=Vₘ.

$$\begin{matrix}y = {v}_{1} - {v}_{2} = {V}_{m} \{ sin ( ω t + δ ) - sin ( ω t ) \} & ( 4 ) \\ ⇒ y = 2 {V}_{m} cos ( ω t + \frac{δ}{2} ) \cdot cos ( δ ) . & ( 5 )\end{matrix}$$

The Cartesian formula relating x and y can be obtained from the parametric equations (3) and (5) by eliminating ωt.

From equations (3) and (5):

$$\begin{matrix}ω t = {sin}^{- 1} ( \frac{x}{{I}_{m 1}} ) + ϕ \\ = {cos}^{- 1} ( \frac{y}{2 {V}_{m} cos δ} ) - \frac{δ}{2} \\ ⇒ \{ {cos}^{- 1} \frac{y}{2 {V}_{m} cos δ} - {sin}^{- 1} \frac{x}{{I}_{m 1}} \} \\ = ( ϕ + \frac{δ}{2} ) \\ ⇒ sin \{ {cos}^{- 1} \frac{y}{2 {V}_{m} cos δ} - {sin}^{- 1} \frac{x}{{I}_{m 1}} \} \\ = sin ( ϕ + \frac{δ}{2} ) \\ ⇒ sin ( {cos}^{- 1} \frac{y}{2 {V}_{m} cos δ} ) \cdot ( {sin}^{- 1} \frac{x}{{I}_{m 1}} ) - \\ cos ( {cos}^{- 1} \frac{y}{2 {V}_{m} cos δ} ) \cdot sin ( {sin}^{- 1} \frac{x}{{I}_{m 1}} ) \\ = sin ( ϕ + \frac{δ}{2} ) \\ ⇒ \frac{\sqrt{{( 2 {V}_{m} cos δ )}^{2} - {y}^{2}}}{2 {V}_{m} cos δ} \cdot \frac{\sqrt{{I}_{m}^{2} - {x}^{2}}}{{I}_{m 1}} - \frac{y}{2 {V}_{m} cos δ} \cdot \frac{x}{{I}_{m 1}} \\ = sin ( ϕ + \frac{δ}{2} ) \\ ⇒ \sqrt{\{ {( 2 {V}_{m} cos δ )}^{2} - {y}^{2} \} \cdot \{ {I}_{m 1}^{2} - {x}^{2} \}} \\ = 2 {V}_{m} {I}_{m 1} cos δ sin ( ϕ + \frac{δ}{2} ) + xy .\end{matrix} \qquad ( 6 )$$

Squaring both sides and rearranging the equation gives:

$${( 2 {V}_{m} cos δ )}^{2} {x}^{2} + 4 {V}_{m} {I}_{m 1} cos δ sin ( ϕ + \frac{δ}{2} ) xy + {I}_{m 1}^{2} {y}^{2} + {( 2 {V}_{m} {I}_{m 1} cos δ sin ( ϕ + \frac{δ}{2} ) )}^{2} - {( 2 {V}_{m} {I}_{m 1} cos δ )}^{2} = 0. \qquad ( 7 )$$

Assume the coefficients of (7) are:

$$A = {( 2 {V}_{m} cos δ )}^{2} ;$$

$$B = 4 {V}_{m} {I}_{m 1} cos δ sin ( ϕ + \frac{δ}{2} ) ;$$

$$C = {I}_{m 1}^{2} ;$$

$$D = {( 2 {V}_{m} {I}_{m 1} cos δ sin ( ϕ + \frac{δ}{2} ) )}^{2} - {( 2 {V}_{m} {I}_{m 1} \cdot cos δ )}^{2}$$

The quadratic equation (7) represents:
an ellipse if B²−4AC<0;
a parabola if B²−4AC=0; and
a hyperbola if B²−4AC>0.

$$\begin{matrix}{B}^{2} - 4 AC = 16 {I}_{m 1}^{2} {V}_{m}^{2} \{ {cos}^{2} δ {sin}^{2} ( ϕ + \frac{δ}{2} ) - {cos}^{2} δ \} \\ = 16 {I}_{m 1}^{2} {V}_{m}^{2} {cos}^{2} δ \{ {sin}^{2} ( ϕ + \frac{δ}{2} ) - 1 \} \\ = - 16 {I}_{m 1}^{2} {V}_{m}^{2} {cos}^{2} δ \cdot {cos}^{2} ( ϕ + \frac{δ}{2} ) .\end{matrix} \qquad ( 8 )$$

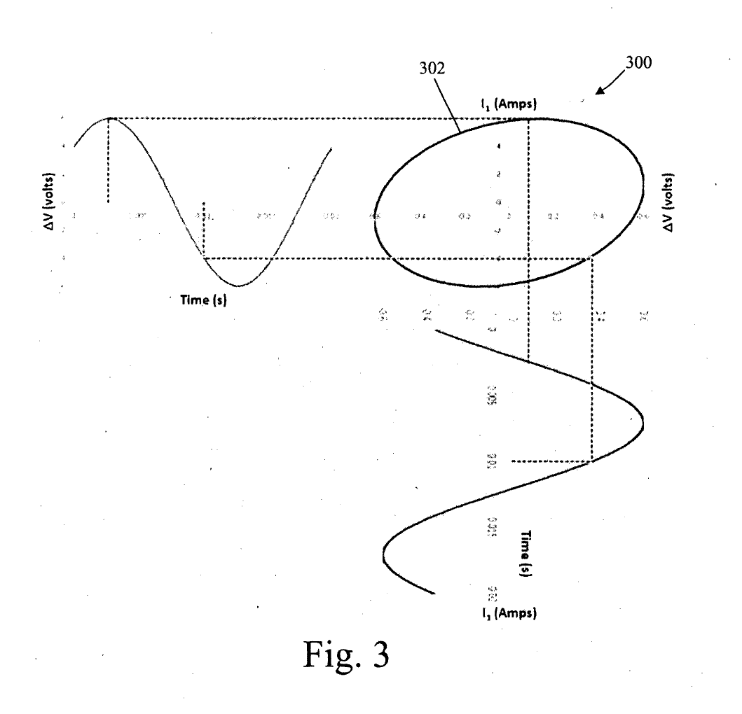

Equation (8) is always a negative term regardless of the values of Iₘ, Vₘ, δ, and φ. Hence, the Cartesian relationship between (v₁−v₂) and i₁ represents an ellipse. The approach is shown in a graph 300 in FIG. 3 wherein the instantaneous values of ΔV(v₁−v₂) and i₁ are measured at a particular time to calculate the corresponding point on the ΔV−I₁ locus 302. The graph 300 in FIG. 3 is drawn at a 0.8 legging power factor. As the phase shift between V₁ and V₂ is normally small, the impact of the angle 5 on the locus is insignificant and can be neglected. The phase shift between I₁ and V₂ (φ) is almost equal to the load impedance phase angle since the phase shift between I₁ and I₂ is negligible. To investigate the impact of the load (Z_{L}) power factor on the proposed locus, the ΔV−I₁ locus is constructed for a 15-kVA, 23001230-V single-phase transformer with the following equivalent circuit parameters referred to the low-voltage side:

R_{eq}=4.45Ω; X_{eq}=6.45 ω; Xₘ=11 kΩ; R_{c}=105 kΩ.

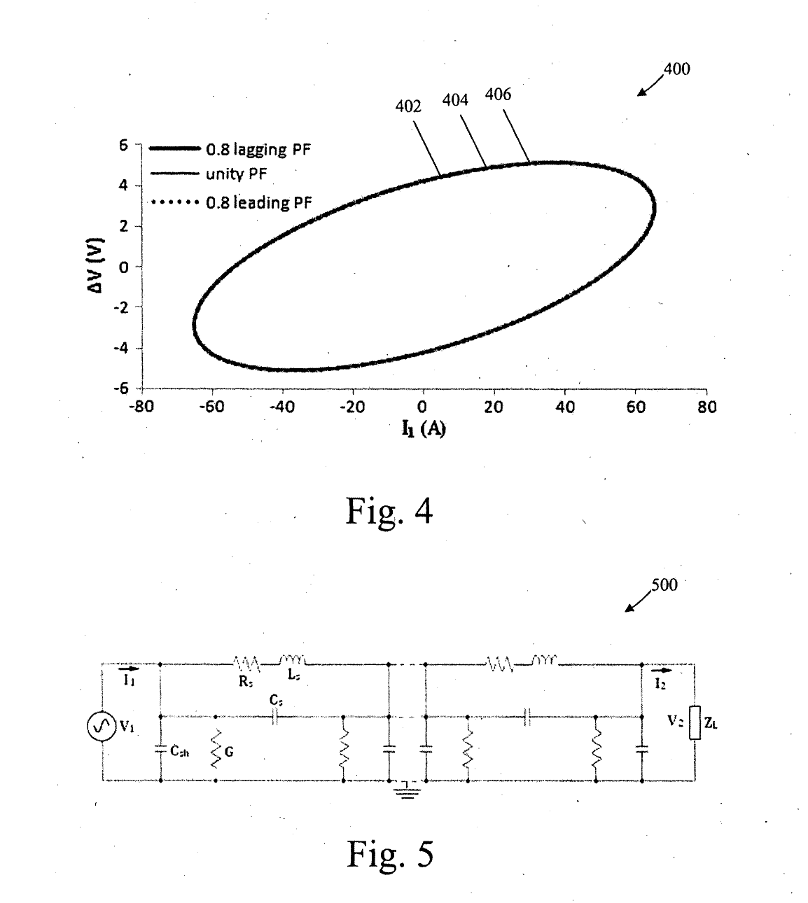

Three operating conditions (0.8 lagging power factor, unity power factor, and 0.8 leading power factor) with constant impedance magnitude were tested, and the corresponding ΔV−I₁ locus for each case was constructed. The three loci, locus 402 corresponding to 0.8 lagging power factor, locus 404 corresponding to unity power factor, and locus 406 corresponding to 0.8 leading power factor, were found to be identical as shown in the graph 400 of FIG. 4. Hence, the load power factor has no impact on the proposed locus.

An example wherein the power transformer is modelled as an equivalent electrical circuit will now be described.

The practical application of any diagnostic technique to detect mechanical damage in a transformer depends on its sensitivity to any change in the distributed inductances and capacitances. The transformer can be modeled with sufficient accuracy as a distributed analog R-L-C circuit. The effect of the iron core has a minimal role to play in an impulse stressed winding. This agrees well with the fact that in a rapid transient condition, the flux lines tend to centre around the conductors rather than penetrating the iron core and for high-frequency components of surges, the iron core acts effectively as an earthed boundary.

Some studies have neglected the effect of distributed shunt conductance which is considered a valid assumption for impulse voltage distribution analysis in the case of a faultless transformer, but may not be adequate in the case of fault diagnosis. Neglecting shunt conductance in the equivalent circuit will eliminate the study of leakage fault inside a transformer which could have been caused by several reasons, such as insulation damage, ground shield, or hot spots. The equivalent model (neglecting shunt conductance) could be ideal for verifying the measured transfer function for interdisk, coil short circuit, and winding displacements. Hence, the model needs some modifications to incorporate the study of leakage faults and partial discharges in the winding. These shortcomings of the computational model can be overcome if parameters which would allow for simulation of ground leakage and voids in the insulation are taken into consideration. The distributed transformer model equivalent circuit 500 shown in FIG. 5 is proposed in this example.

In this model, a single transformer winding is divided into a cascaded pi-network comprising self/mutual inductances, resistance, series/shunt capacitances, and shunt dielectric conductance. For simplicity, it is assumed that the mutual inductances are lumped into series inductances; this assumption is widely used in the literature. The model parameters were calculated based on practical FRA measurements performed on the three-phase low-voltage windings of a 250-MVA, 345/16-kV, 102-disk transformer.

Use of the distributed parameter model for the power transformer will allow simulating different types of faults on one-hundred and two individual internal disks used in this model. The parameters of the distributed model 500 shown in FIG. 5 can also be determined from the geometrical dimensions of the transformer which makes the model suitable for different fault studies. There is a direct relationship between the geometric configuration of the winding and core within a transformer and the distributed parameters of the transformer. Table I outlines a number of physical parameters of the transformer distributed network and the types of faults these are associated with.

TABLE I
TRANSFORMER ELECTRICAL PARAMETERS
AND FAULT-TYPE RELATIONSHIP

| Physical Parameter | Type of Fault |
|---|---|
| Inductance | Disk deformation, local breakdown, winding |
| | short circuits. |
| Shunt Capacitance | Disk movements, buckling due to large |
| | mechanical forces, moisture ingress, loss of |
| | clamping pressure. |
| Series Capacitance | Ageing of insulation, disk space variation. |
| Resistance | Shorted or broken disk, partial discharge. |

The equivalent model 500 was simulated and used to obtain a locus plot under different load conditions, as described below, to provide a reference locus plot, and information that is indicative of the reference locus plot.

One-hundred and two disks (two turns per disk) of the model shown in FIG. 5 were simulated using PSIM software. The model was energized by an ac, 50-Hz voltage source of low amplitude and the instantaneous values of v₁, v₂, and i₁ were recorded at a time step of 10 μs. In this way, a ΔV−I₁ locus of a healthy transformer can be constructed and is considered as a reference or fingerprint of this transformer. When a transformer experiences an event that results in deformation of the windings, the transformer impedance will vary and this alters the transformer ΔV−I₁ locus diagram.

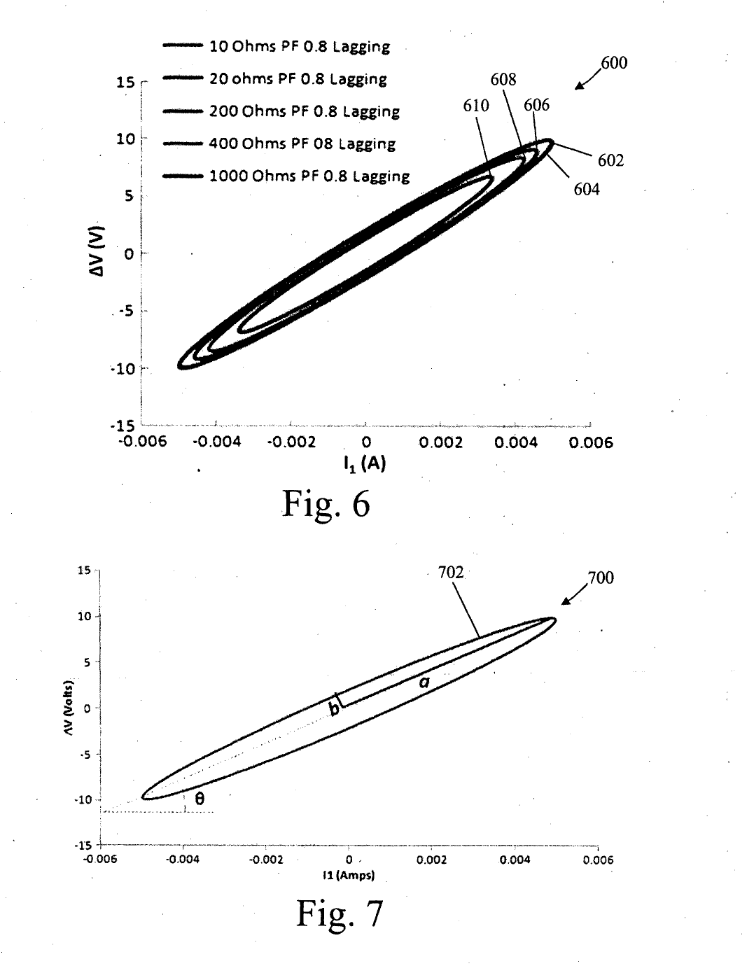

As has been shown in FIG. 4, the load power factor with constant impedance magnitude does not have any impact on the locus plot. Different load levels at constant power factor were simulated to investigate the effect of load magnitude variation on the proposed locus. FIG. 6 shows a graph 600 of locus plots for different load levels, including a locus 602 corresponding to a load level of 10Ω, a locus 604 corresponding to a load level of 20Ω, a locus 606 corresponding to a load level of 200Ω, a locus 608 corresponding to a load level of 400Ω, and a locus 610 corresponding to a load level of 1000 Ω.

As shown in the graph 600 of FIG. 6, increasing the load level from 10 to 20Ω (100% increment) does not have any impact on the proposed locus. The effect of load magnitude on the proposed locus will take place when there is a significant change in load level as can be seen when the load magnitude is increased to 200Ω. The effect of this significant increment in load magnitude on reducing the entire area of the ΔV−I₁ locus is dearly shown in FIG. 6. However, all loci will have the same common major axis and same centroid. In the model under study, a 10∠36.87° Ω is simulated as the load impedance.

FIG. 7 is a graph 700 showing a ΔV−I₁ locus 702 of a healthy transformer. The locus 702 is considered to be that of a healthy transformer as no changes were made to the model 500 parameters. Different mechanical faults were then simulated on the model 500 and the corresponding ΔV−I₁ loci were plotted and compared with the healthy locus 702 of FIG. 7, as discussed in more detail later. The diagnosis of the problem is achieved by comparing the healthy transformer fingerprint 702 and the faulty one to identify any differences and, hence, to determine a possible fault type.

In this example, a Matlab code was developed and used to measure some unique features of the ΔV−I₁ locus such as the semimajor and semi-minor axes lengths and the angle between the major axis and the horizontal axis. These parameters are shown in the locus 702 of FIG. 7 as a, b, and θ, respectively.

To identify the features of winding deformation and effect of model parameters on the ΔV−I₁ locus, faults such as interdisk fault, axial displacement, leakage (disk to ground fault), and buckling stress of inner winding were simulated and compared with the healthy locus.

### A. Interdisk Fault

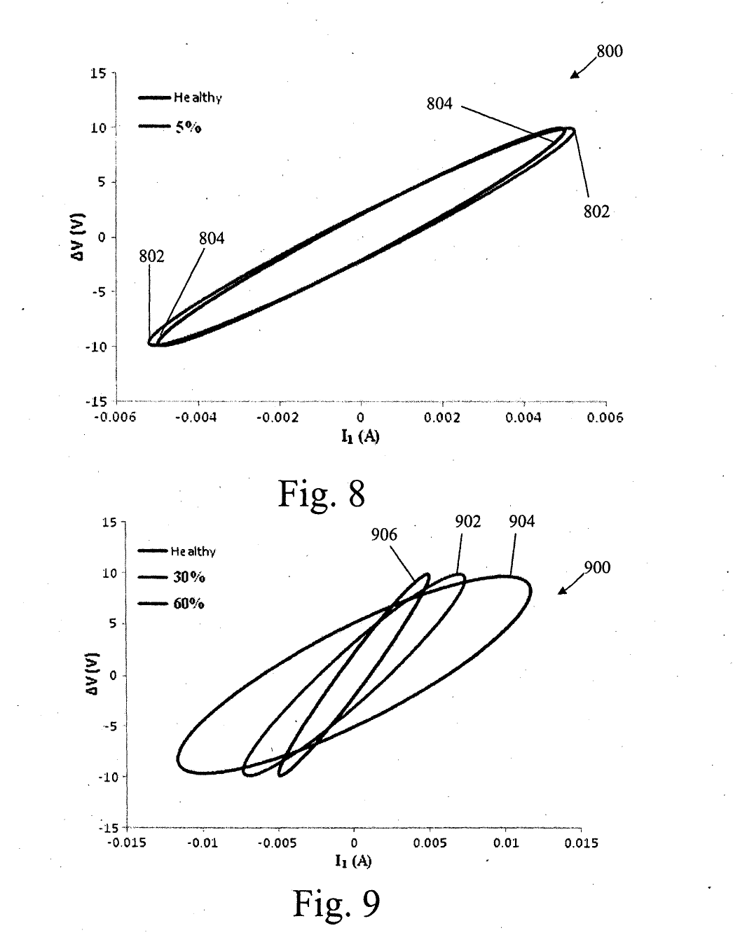

The interdisk fault is considered as the most common fault of power transformers. Studies show that about 80% of transformer breakdowns are attributed to interdisk fault. In this example, different numbers of disks have been short-circuited to find their impact on the ΔV−I₁ locus. To show the accuracy of the model to detect this fault, 5% of the coils have been short-circuited and the proposed locus 802 is compared to a healthy locus 804 as shown in the graph 800 of FIG. 8, which clearly shows the difference between the two loci.

The graph 900 of FIG. 9 shows locus 902 for 30% fault disks and locus 904 for 60% faulty disks compared to healthy locus 906. It can be observed from FIGS. 8 and 9 that, as the number of faulty disks increase, the locus rotates further in the clockwise direction and its entire area increases.

### B. Axial Displacement

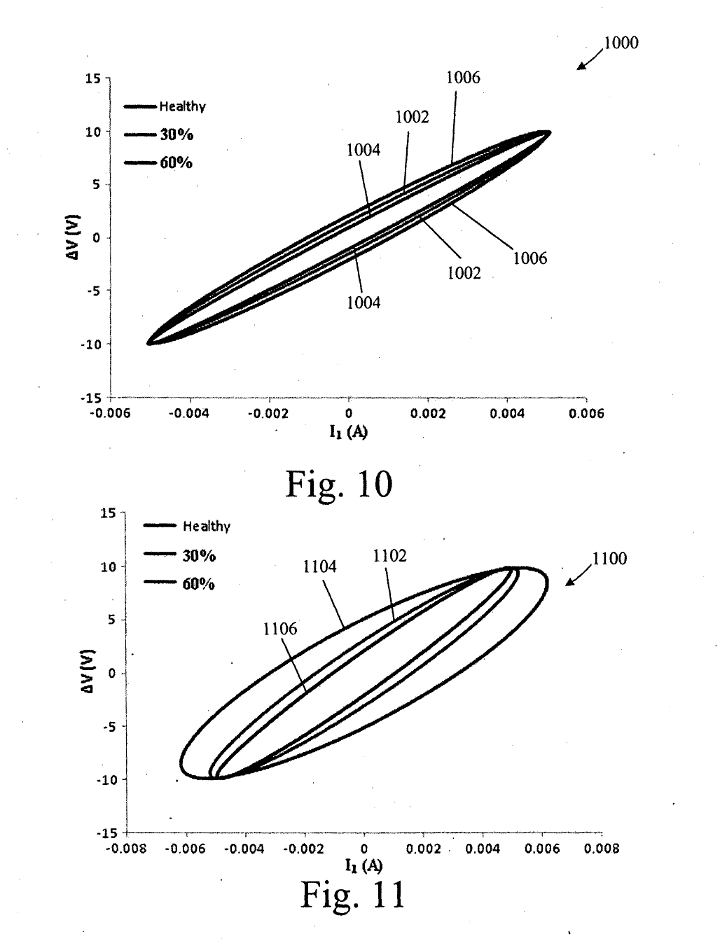

An axial displacement fault occurs due to a magnetic imbalance between the low- and high-voltage windings due to short-circuit currents. The axial displacement between the magnetic centres of the windings will result in unbalanced magnetic force components in each half of the winding which leads to a change in its relative position. Leaving this fault unattended can cause winding collapse or failure of the end-supporting structure due to its progressive nature. This type of fault can be simulated by changing the mutual and self inductances of particular disks. The change in capacitance can be neglected. In this example, axial displacement is modelled by a 10% decrease in the inductance. Graph 1000 of FIG. 10 shows the effect of axial displacement of 30% and 60% disks on the ΔV−I₁ locus, as can be seen from locus 1002 which corresponds to axial displacement of 30% disks, locus which corresponds to axial displacement of 60% disks, and locus 1006 of a healthy transformer.

FIG. 10 shows that axial displacement will decrease the area of the faulty locus compared with the healthy one. Increasing the number of faulty disks will further decrease the locus area but there is no rotation in the locus major axis.

### C. Buckling Stress

Leakage flux and current in the windings causes radial force on windings. This force pulls the inner windings close to the core (buckling stress), while pushing the outer winding toward the limb (tensile stress). Buckling stress can be simulated in the distributed model by reducing the interwinding capacitance and the mutual inductance between the windings at the position of deformation. Furthermore, the shunt capacitance is increased due to the reduction of the distance between the winding and the core.

In this example, forced buckling is modelled by increasing the shunt capacitance by 10%, and decreasing the inductance and series capacitance by 10%. The effect of this fault on the proposed locus is shown in graph 1100 of FIG. 11. In this example, locus 1102 corresponds to forced buckling of 30% disks, locus 1004 corresponds to axial displacement of 60% disks, and locus 1006 corresponds to a healthy transformer. Unlike the axial displacement effect, buckling stress increases the locus area, and the major axis will slightly rotate in the clockwise direction as the number of faulty disks increases. The slight locus rotation discriminates this type of fault from the interdisk fault.

### D. Leakage (Disk to Ground) Fault

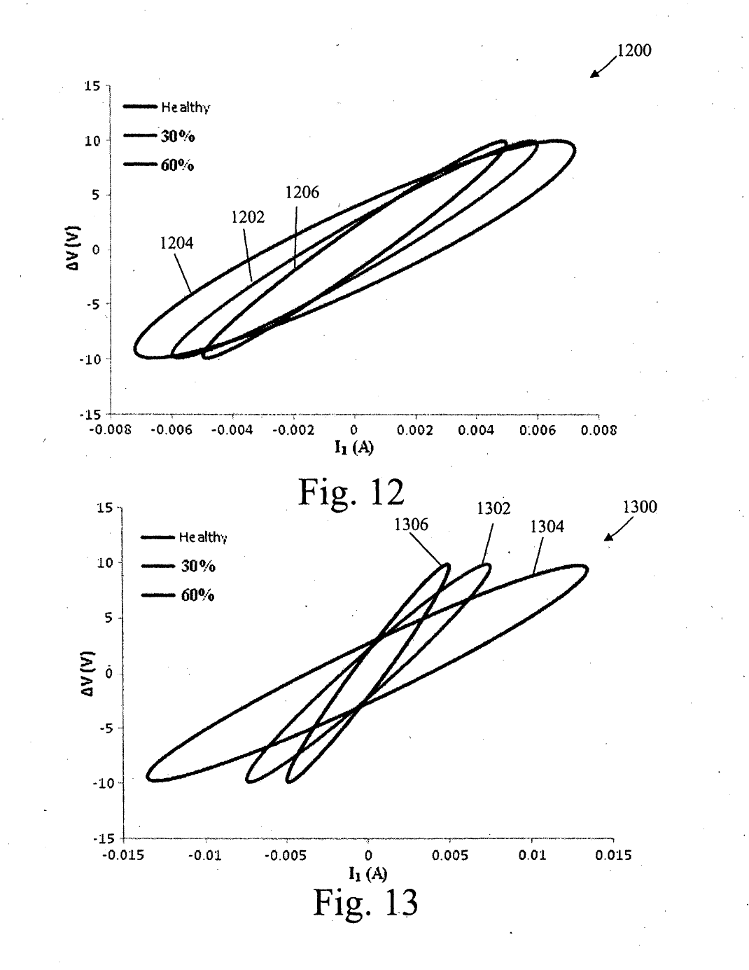

Insulation damage, ground shield damage, abrasion, high moisture content in the winding, hotspot and aging insulation, which reduces its dielectric strength, are the main reasons for leakage fault inside a transformer. This type of fault can be simulated by increasing the shunt conductance and shunt admittance. Graph 1200 of FIG. 12 shows the effect of increasing the shunt admittance and shunt conductance by 70% on the proposed locus. Graph 1200 shows locus 1202 which corresponds to a disk-to-ground fault of 30% disks, locus 1204 which corresponds to a disk-to-ground fault of 60% disks, and locus 1206 which corresponds to a healthy transformer. As can be seen in FIG. 12, the locus area is increasing and the major axis is rotating in a clockwise direction, similar to the case of interdisk fault. However, the locus area in the case of interdisk fault is larger than the corresponding locus in the case of a leakage fault for the same number of faulty disks.

### E. Disk Space Variation

Mechanical displacements of power transformer windings can occur due to short-circuit currents. Disk-space variation is one of the frequently occurring mechanical faults in power transformers where the geometry of transformer windings will be altered. For such faults, the effect of inductance can be neglected with respect to series capacitance at the location of the fault. Due to the fact that at the low-frequency range the transformer winding response is dominated by inductance and the effect of the series capacitor is almost negligible, unless there is a significant disk space variation, this type of fault is more difficult to detect using this technique. In the example, a significant disk space variation fault is simulated by increasing the series capacitor by 70%. The effect of such fault on the proposed locus is shown in graph 1300 of FIG. 13. In this example, locus 1302 corresponds to disk space variation of 30% disks, locus 1304 corresponds to disk space variation of 60% disks, and locus 1306 corresponds to a healthy transformer. By increasing the number of faulty disks, the locus is rotating in the clockwise direction and the length of the major axes is significantly increasing.

Differences between the test locus plots, as simulated above, and the reference locus plot can be determined so as to determine the type of fault. There are a number of different techniques that can be used to determine such difference, as described in greater detail below.

### A. Visual Discrimination

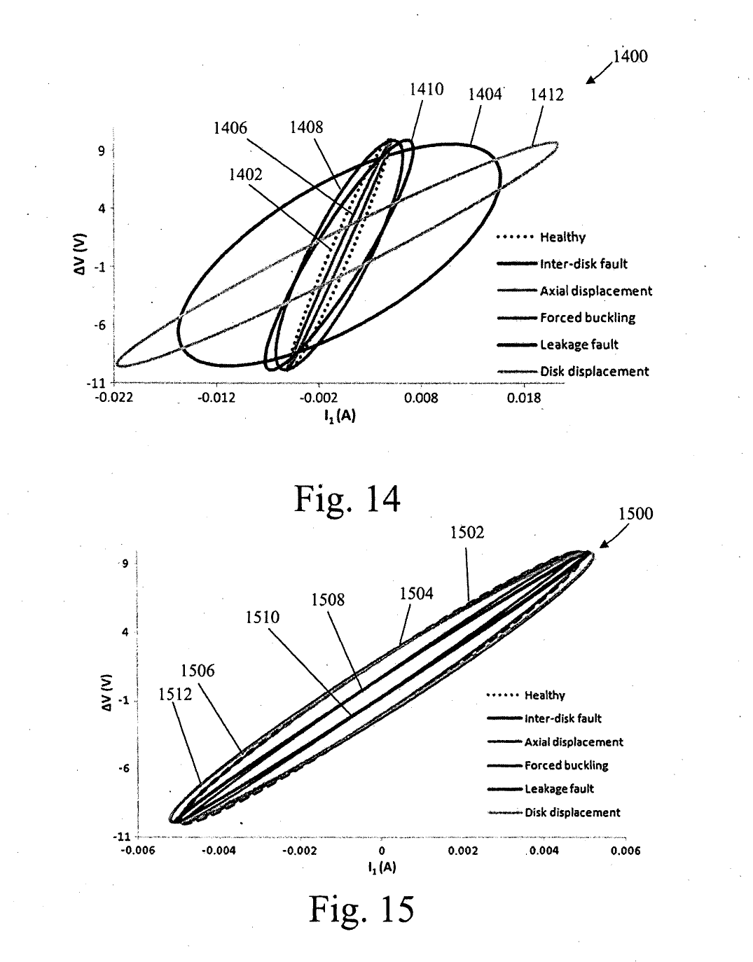

Discrimination between different types of faults can be visibly observed from the ΔV−I₁ locus area and major axis rotation. To show this, different types of faults discussed before are simulated on 80% of the overall disks of the transformer model, and the ΔV−I₁ loci for all of them with respect to the healthy locus are compared as shown in graph 1400 of FIG. 14. Graph 1400 shows locus 1402 corresponding to a healthy transformer, locus 1404 corresponding to an interdisk fault, locus 1406 corresponding to an axial displacement fault, locus 1408 corresponding to a forced bucking fault, locus 1410 corresponding to a leakage fault, and locus 1412 corresponding to a disk displacement fault.

FIG. 14 shows that the locus area is increasing in all faulty cases with respect to the area of the healthy locus except in the case of axial displacement where the area is decreased. The locus major axis in the case of axial displacement is aligning with the healthy major axis. Interdisk fault has a significant increase in the locus area and its major axis rotates significantly in the clockwise direction. Locus area increases in case of forced buckling and leakage fault and both loci rotate in the clockwise direction with respect to the healthy locus. However, the angle of rotation in case of leakage fault is slightly higher. The disk displacement major axis length significantly increases and rotates in the clockwise direction.

Table II summarizes the effect of studied faults on the locus area and locus major axis rotation in relation to the healthy locus for visual discrimination.

TABLE II
EFFECT OF FAULTS ON LOCUS
AREA AND AXIS ROTATION

| Fault Type | Area | Rotation |
|---|---|---|
| Inter disk | Significant increase | Large |
| disk space variation | Increase | Very large |
| Leakage Fault | Increase | Large |
| Forced buckling | Increase | Slight |
| Axial displacement | Decrease | None |

To show the accuracy of the proposed technique to detect faults simulated in a small number of disks, all types of faults are simulated in five disks (4.9%) of the overall disks, and the corresponding ΔV-I₁ loci are plotted as shown in graph 1500 of FIG. 15. Graph 1500 shows locus 1502 corresponding to a healthy transformer, locus 1504 corresponding to an interdisk fault, locus 1506 corresponding to an axial displacement fault, locus 1508 corresponding to a forced buckling fault, locus 1510 corresponding to a leakage fault, and locus 1512 corresponding to a disk displacement fault.

The same trend can be observed in the impact of each fault on the locus as discussed before. However, it is more difficult to visually discriminate different types of faults in this case compared to the case of a higher number of faulty disks as illustrated previously with respect to FIG. 14. A software model is developed to automate the discrimination process and to identify the fault type based on some features of the ellipse as wilt be discussed in a later section.

### B. Discrimination Using Ellipse Features

As has been shown in the mathematical proof and simulation results earlier, the ΔV−I₁ locus is always representing an ellipse. Some unique features of the ellipse can be used to compare different loci and to identify the type of fault within the power transformer. These features include ellipse centroid, the major and minor axes lengths (a and b, respectively), the angle between the major axis, and the horizontal axis (θ). A Matlab code has been developed and is used to measure these parameters and to calculate an ellipse eccentricity. The ellipse eccentricity is used to describe the ellipse general proportion and is given by:

$$c = \sqrt{1 - {( \frac{b}{a} )}^{2}} . \qquad ( 9 )$$

To identify the type of fault based on eccentricity, angle of rotation, major-axis length, and minor-axis length, each fault has been simulated on a different number of disks starting from five disks to 100 disks, and these parameters have been calculated for each fault using the developed software as shown in Table III.

TABLE III
EFFECT OF DIFFERENT FAULTS ON LOCUS
ECCENTRICITY AND AXIS ROTATION

| | T-T | | Axial | | Forced | | Leakage | | Disk space | |
|---|---|---|---|---|---|---|---|---|---|---|
| faulty | SC fault | | displacement | | buckling | | fault | | variation | |
| disks | e | θ | e | θ | e | θ | e | θ | e | θ |
| 5 | 0.05 | 2.15 | 0.17 | 0 | 0.60 | 1.01 | 0.60 | 1.05 | 0.02 | 2.23 |
| 10 | 0.24 | 7.26 | 0.20 | 0 | 0.64 | 1.56 | 0.63 | 1.16 | 0.02 | 8.26 |
| 15 | 0.37 | 8.12 | 0.21 | 0 | 0.65 | 1.71 | 0.65 | 1.60 | 0.03 | 9.38 |
| 20 | 0.42 | 9.59 | 0.28 | 0 | 0.67 | 1.82 | 0.73 | 1.71 | 0.04 | 9.71 |
| 25 | 0.47 | 10.05 | 0.29 | 0 | 0.68 | 2.01 | 0.75 | 1.76 | 0.06 | 10.18 |
| 30 | 0.55 | 11.15 | 0.35 | 0 | 0.69 | 2.92 | 0.79 | 1.90 | 0.08 | 11.71 |
| 35 | 1.03 | 12.28 | 0.38 | 0 | 0.7 | 3.19 | 0.81 | 2.14 | 0.09 | 12.60 |
| 40 | 1.11 | 13.40 | 0.40 | 0 | 0.71 | 4.69 | 0.85 | 2.52 | 0.12 | 13.53 |
| 45 | 1.31 | 13.75 | 0.42 | 0 | 0.73 | 4.97 | 0.88 | 2.74 | 0.16 | 14.25 |
| 50 | 1.69 | 14.21 | 0.46 | 0 | 0.73 | 5.69 | 0.97 | 2.95 | 0.18 | 14.81 |
| 55 | 3.13 | 14.24 | 0.47 | 0 | 0.75 | 6.15 | 1.03 | 3.11 | 0.19 | 15.94 |
| 60 | 3.43 | 15.43 | 0.52 | 0 | 0.81 | 6.43 | 1.12 | 3.56 | 0.21 | 16.36 |
| 65 | 4.00 | 15.84 | 0.56 | 0 | 0.83 | 7.27 | 1.33 | 3.58 | 0.23 | 16.48 |
| 70 | 4.21 | 16.50 | 0.57 | 0 | 0.85 | 7.97 | 1.37 | 3.72 | 0.25 | 17.18 |
| 75 | 4.54 | 16.71 | 0.58 | 0 | 0.87 | 8.47 | 1.68 | 3.98 | 0.26 | 17.82 |
| 80 | 4.6 | 17.05 | 0.59 | 0 | 0.89 | 8.82 | 1.68 | 4.54 | 0.27 | 18.09 |
| 85 | 5.2 | 18.85 | 0.61 | 0 | 0.91 | 9.22 | 1.80 | 4.74 | 0.29 | 19.13 |
| 90 | 5.6 | 19.86 | 0.63 | 0 | 0.66 | 9.53 | 1.90 | 4.87 | 0.32 | 19.95 |
| 95 | 5.7 | 20.89 | 0.63 | 0 | 0.64 | 10.33 | 2.01 | 5.07 | 0.38 | 20.93 |
| 100 | 6.61 | 21.10 | 0.65 | 0 | 0.66 | 11.05 | 2.20 | 5.14 | 0.49 | 21.55 |

Table III shows the percentage difference in eccentricity (e) and the angle of rotation of the major axis (θ) for different types of faults with respect to the healthy locus.

The interdisk fault has a significant increase in the eccentricity and angle of rotation as the number of faulty disks increases. Axial displacement does not introduce any effect on the axis rotation, and the value of eccentricity slightly increases as the number of faulty disks increase. The eccentricity in forced buckling and leakage faults slightly increases with the increase of faulty disks; the eccentricity increment is more noticeable in case of a leakage fault. On the other hand, the Increase in the angle of rotation with the increase of faulty disks is more significant in case of forced buckling than the leakage fault especially for a large number of faulty disks. The disk space variation has a minor impact on the eccentricity and a significant impact on the angle when the number of faulty disks is increased. Based on the range of the percentage differences of these parameters for each fault, the Matlab code is modified to identify the type of fault within the transformer. Five case studies are used to validate the developed

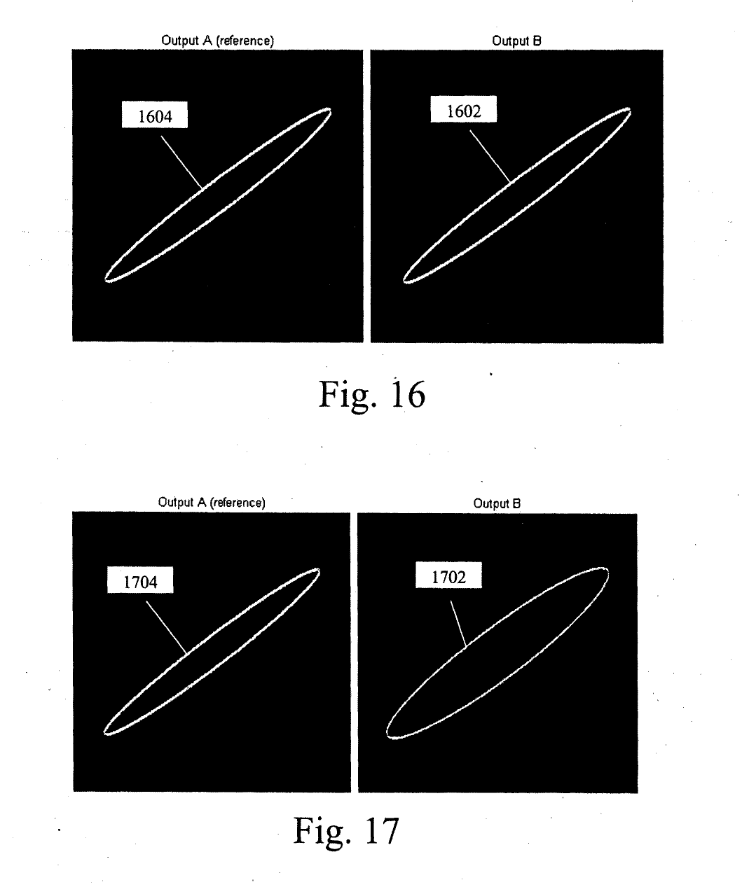

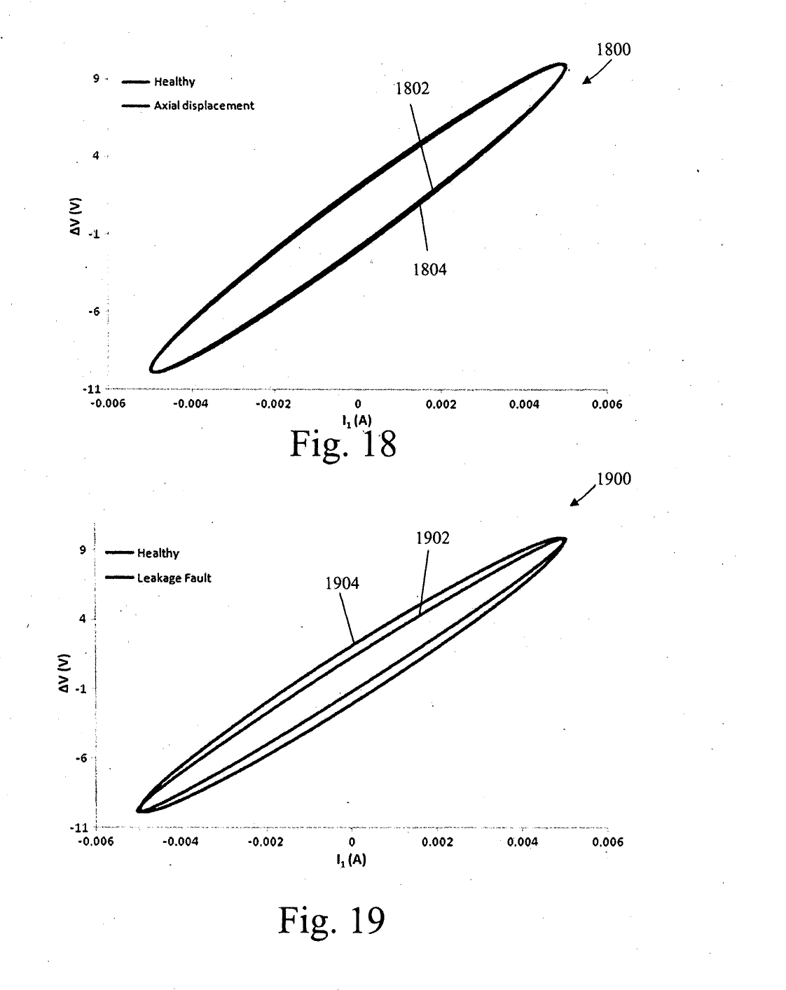

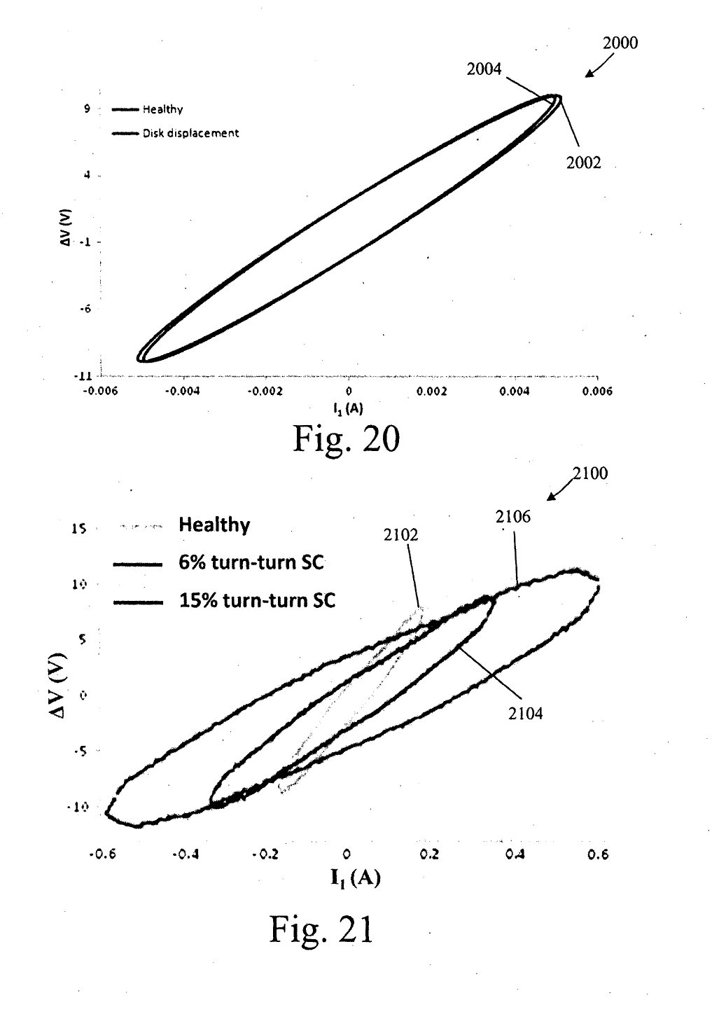

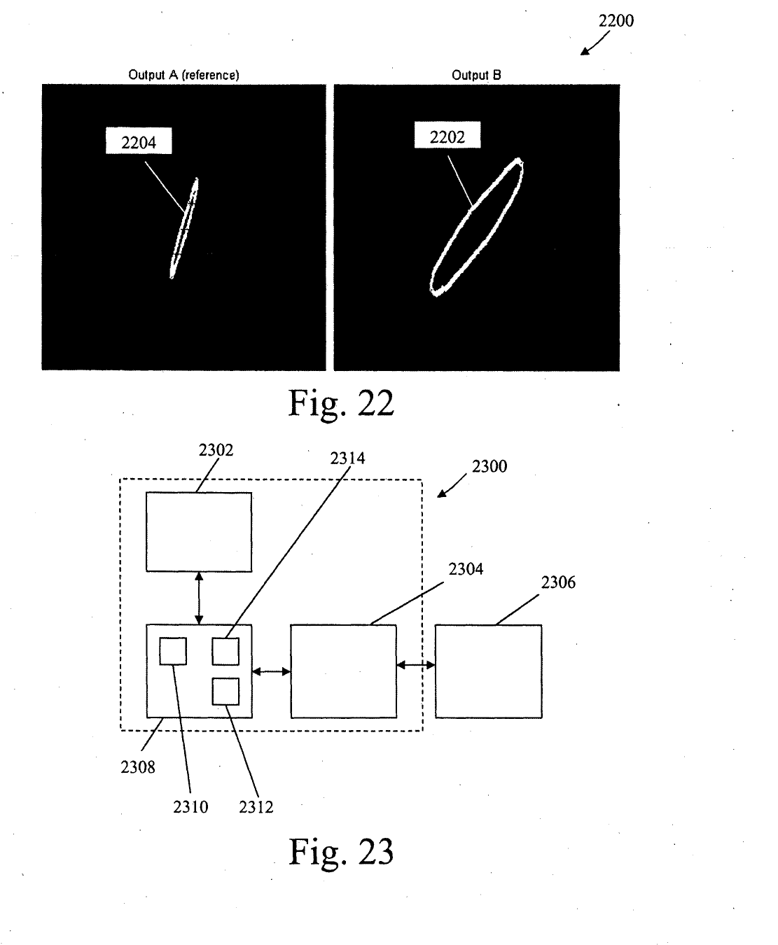

approach as follows:
Case 1) Two identical loci are compared using the developed software. The developed software converts the color of the two loci into white with a black background to perform the calculations of ellipse centroid, major and minor axes lengths, eccentricity, and the angle between the major axis and the horizontal axis. The software produces the two loci 1602, 1604 shown in FIG. 16 and shows that there is no difference in eccentricity and angle of rotation of the two loci and, hence, the software recommends a healthy transformer for this case.
Case 2) Forced buckling stress is simulated in 44 disks, and the faulty locus 1702 is compared with the healthy locus 1704 using the developed software (see FIG. 17). The software gives a 0.72% difference in eccentricity and 4.95% difference in the angle and recommends a forced buckling fault.
Case 3) An axial displacement fault simulated in six disks and the faulty locus 1802 and the healthy locus 1804 shown in the graph 1800 of FIG. 18 are compared using the developed software. The software gives a 0.19% difference in eccentricity and 0% difference in the angle and recommends an axial displacement fault.
Case 4) A leakage fault is simulated in three disks, and the faulty locus 1902 and the healthy locus 1904 shown in graph 1900 of FIG. 19 are compared using the developed software. The software gives a 0.40% difference in eccentricity and a 0.61% difference in the angle and recommends a forced buckling fault.
Case 5) A disk space variation simulated in 1 disk and the faulty locus 2002 and the healthy locus 2004 shown in graph 2000 of FIG. 20 are compared using the developed software. The software gives a 0.005% difference in eccentricity and 1.6% difference in the angle and recommends a disk space variation.
Case 6) Laboratory experimental testing was performed on a 0.5-kVA, 150/170-V single-phase transformer. The transformer is loaded by a 54Ω resistor, and a turn-turn short circuit is created on 6% and 15% of the low-voltage winding. The ΔV−I₁ locus of the transformer is constructed using a digital oscilloscope. A healthy locus 2102, a faulty locus 2104 corresponding to the turn-turn short circuit on 6% of the low-voltage winding, and a faulty locus 2106 corresponding to the turn-turn short circuit on 15% of the low-voltage winding are compared as shown in graph 2100 of FIG. 21 which shows a significant change in the locus area as the number of faulty turns increases. The healthy and 6% short-circuit turns loci were fed to the developed software, the percentage difference in eccentricity calculated by the software is 0.21% and the percentage difference in the angle of rotation calculated by the software is 11.9%; these differences are clearly visible in the two loci, the faulty locus 2202 and the healthy locus 2204, shown in FIG. 22 that are generated by the developed software. The significant difference in the angle of rotation aligns well with the range of the turn-to-turn short-circuit case shown in Table III.

In summary, the above examples illustrate a method 100 to identify mechanical faults within a power transformer. In one embodiment, the method 100 comprises constructing a locus diagram of the input and output voltage difference of a particular transformer winding on the axis and the winding input current on the axis. This locus is considered as the fingerprint of the transformer. Any mechanical fault will alter this locus in a unique way and, hence, fault detection as well as fault type can be identified.

The method 100 also comprises a digital image processing technique based on measuring and comparing some features of the loci to identify the possible fault type. These features include image centroid, the major and minor axes lengths, eccentricity, and the angle of rotation. Simulation results show that each fault has a unique impact on these parameters.

The disk-space variation has the lowest impact on eccentricity and largest impact on the angle of rotation. The axial displacement does not have any impact on the angle of rotation and has a minor impact on eccentricity. The interdisk fault has a significant impact on angle of rotation and eccentricity while the leakage fault has a moderate impact on both parameters. Forced buckling has a moderate impact on the angle while its impact on the eccentricity is minor.

The method 100 may utilise existing metering devices attached with the power transformer, and the method 100 can be implemented online as it is performed at the mains frequency. A test locus can be plotted every cycle (20 ms based on a 50-Hz power network), and the test locus can be compared with a previous locus using the developed mage-processing code to immediately identify any changes. If any changes are identified, the method 100 can comprise a step of generating an early warning signal.

An example system 2300 will now be described with reference to FIG. 23. In this example, the system 2300 comprises data storage 2302 that is arranged to store information that is indicative of at least one property of a reference locus plot associated with a reference power transformer. The system 2300 also comprises a current and voltage measurement system 2304 arranged to measure an input current and a voltage difference between an input voltage and an output voltage of a power transformer 2306 while the power transformer is in operation.

The system 2300 also comprises a processor 2308 having a test locus plot processing module 2310 arranged to derive information that is indicative of at least one property of a test locus plot from the measured input current and voltage difference of the power transformer. The processor 2308 also comprises a comparison processing module 2312 that is arranged to compare the information that is indicative of the at least one property of the test locus plot to information that is indicative of at least one property of a reference locus plot associated with a reference power transformer so as to determine whether a characteristic of at least one winding of the power transformer differs from that of the reference power transformer.

The processor 2308 of the system 2300 also comprises a characteristic categorising processing module 2314 arranged to categorise the characteristic of the at least one winding based on the comparing step. In this example, the characteristic processing module 2314 is arranged to categorise the characteristic of the at least one winding as any one of the group comprising: an interdisk fault, an axial displacement fault, a buckling stress fault, a leakage (disk to ground) fault, and a disk space variation fault. Such categorisation may be conducted in accordance with steps of the method 100.

Further, the comparison processing module 2314 is arranged to compare the test locus plot to the reference locus plot so as to determine visual differences therebetween, and the system 2300 is arranged to determine whether the characteristic of the at least one of the windings of the power transformer differs from that of the reference power transformer based on any visual differences between the test locus plot and the reference locus plot.

The processor 2308 and the data storage 2302 elements of the system 2300 may be components of a computer system, such as a desktop computing device or a server, and the current and voltage measurement system 2304 may comprise existing metering devices connected to the power transformer 2306. The computer system may be arranged to interface with the current and voltage measurement system 2304, such as via a network connection or similar, and be arranged to receive measurements taken by the current and voltage measurement system 2304 via the network. In one embodiment, the system 2300 is arranged to generate an alert if the system 2300 determines that the characteristic of the at least one winding of the power transformer differs from that of the reference power transformer by a predefined amount. The generated alert may be communicated, such as via a network connection, to an appropriate organisation, such as an organisation that is responsible for maintenance of the power transformer 2306, so as to facilitate the organisation in investigating any determined faults in respect of the power transformer 2306.

Having described preferred embodiments of the invention with reference to the accompanying drawings, it is to be understood that the invention is not limited to those precise embodiments and that various changes and modifications could be effected therein by one skilled in the art without departing from the spirit or scope of the invention as defined in the appended claims.

For example, it is envisaged that the method 100 or the system 2300 may be implemented as a computer program that is arranged, when loaded into a computing device, to instruct the computing device to operate in accordance with the method or the system 2300.

Further, or alternatively, the method 100 or the system 2300 may be provided in the form of a computer readable medium having a computer readable program code embodied therein for causing a computing device to operate in accordance with the method 100 or the system 2300.

Still further, or alternatively, the method 100 or the system 2300 may be provided in the form of a data signal having a computer readable program code embodied therein to cause a computing device to operate in accordance with the method 100 or the system 2300.

In the claims which follow and in the preceding description of the invention, except where the context requires otherwise due to express language or necessary implication, the word “comprise” or variations such as “comprises” or “comprising” is used in an inclusive sense, i.e. to specify the presence of the stated features but not to preclude the presence or addition of further features in various embodiments of the invention.

1-58. (canceled)

59. A method of determining a characteristic of a power transformer, the power transformer having an input current, an input voltage, an output current and an output voltage, the method comprising the steps of:
measuring the input current and a voltage difference between the input voltage and the output voltage of the power transformer while the power transformer is in use within a power distribution network;
deriving information that is indicative of at least one property of a test locus plot from the measured input current and voltage difference of the power transformer, and
comparing the information that is indicative of the at least one property of the test locus plot to information that is indicative of at least one property of a reference locus plot associated with a reference power transformer so as to determine whether a characteristic of the power transformer differs from that of the reference power transformer.

60. The method of claim 59, wherein the step of comparing comprises comparing the test locus plot to the reference locus plot so as to determine visual differences therebetween, and/or comparing ellipse features of the test locus plot to ellipse features of the reference locus plot so as to determine differences therebetween.

61. The method of claim 59, wherein the power transformer is energized by an alternating current having a mains frequency of an electrical network to which the power transformer is, in use, connected.

62. The method of claim 59, wherein the characteristic is a characteristic of at least one winding of the power transformer.

63. The method of claim 62, wherein the characteristic of the at least one winding of the power transformer is a characteristic for which a chance of the power transformer failing increases if the power transformer is subjected to a fault if the characteristic differs from that of the reference power transformer.

64. The method of claim 62, further comprising a step of categorising the characteristic of the at least one winding based on the comparing step.

65. The method of claim 64, wherein the characteristic of the at least one winding is categorised as any one of the group comprising: an interdisk fault, an axial displacement fault, a buckling stress fault, a leakage (disk to ground) fault, and a disk space variation fault.

66. The method of claim 62, wherein the step of comparing comprises comparing the test locus plot to the reference locus plot so as to determine visual differences therebetween, and the method comprises the step of determining whether the characteristic of the at least one of the windings of the power transformer differs from that of the reference power transformer based on any visual differences between the test locus plot and the reference locus plot.

67. The method of claim 66, wherein visual differences that are determined include a rotation of the test locus plot compared to the reference locus plot, and/or a change in an area of an internal region of the test locus plot compared to the reference locus plot.

68. The method of claim 66, wherein determined visual differences between the test locus plot and the reference locus plot are used to categorise the characteristic of the at least one winding.

69. The method of claim 66, wherein determined visual differences between the test locus plot and the reference locus plot are used to determine a magnitude of the characteristic of the at least one winding.

70. The method of claim 62, wherein the step of comparing comprises comparing ellipse features of the test locus plot to ellipse features of the reference locus plot so as to determine differences therebetween, and the method comprises the step of determining whether the characteristic of the at least one of the windings of the power transformer differs from that of the reference power transformer based on any differences between the ellipse features of the test locus plot and the reference locus plot.

71. The method of claim 70, wherein ellipse feature differences that are determined include an ellipse centroid, major and/or minor axes lengths (a and b respectively), an angle between the major axis and a horizontal axis (θ), and an ellipse eccentricity.

72. The method of claim 70, wherein determined ellipse feature differences between the test locus plot and the reference locus plot are used to categorise the characteristic of the at least one winding.

73. The method of claim 70, wherein determined ellipse feature differences between the test locus plot and the reference locus plot are used to determine a magnitude of the characteristic of the at least one winding.

74. The method of claim 59, wherein the input current and the voltage difference of the power transformer are measured each cycle of the mains frequency and wherein the step of determining whether the characteristic of the power transformer differs from that of the reference power transformer is performed based on each set of input current and voltage difference as measured each cycle of the mains frequency.

75. A system for determining a characteristic of a power transformer, the power transformer having an input current, an input voltage, an output current and an output voltage, the system comprising:
data storage arranged to store information that is indicative of at least one property of a reference locus plot associated with a reference power transformer,
a current and voltage measurement system arranged to measure the input current and a voltage difference between the input voltage and the output voltage of the power transformer while the power transformer is in use within a power distribution network;
a test locus plot processing module arranged to derive information that is indicative of at least one property of a test locus plot from the measured input current and voltage difference of the power transformer; and
a comparison processing module that is arranged to compare the information that is indicative of the at least one property of the test locus plot to information that is indicative of at least one property of a reference locus plot associated with a reference power transformer so as to determine whether a characteristic of the power transformer differs from that of the reference power transformer.

76. The system of claim 75, wherein the comparison processing module is arranged to compare the test locus plot to the reference locus plot so as to determine visual differences therebetween, and/or to compare ellipse features of the test locus plot to ellipse features of the reference locus plot so as to determine differences therebetween.

77. The system of claim 75, wherein the characteristic is a characteristic of at least one winding of the power transformer.

78. The system of claim 77, wherein the characteristic of the at least one winding of the power transformer is a characteristic for which a chance of the power transformer failing increases if the power transformer is subjected to a fault if the characteristic differs from that of the reference power transformer.
